(19) United States
(12) Patent Application Publication
(10) Pub. No.: US 2001/0048618 A1
(43) Pub. Date: Dec. 6, 2001

(54) Memory board

(76) Inventor: Kazunori Shionoya, Toyohashi-Shi (JP)

Correspondence Address: Platon N. Mandros, BURNS, DOANE, SWECKER & MATHIS, L.L.P., P.O. Box 1404, Alexandria, VA, 22313-1404, US

(21) Appl. No.: 09/824,836

(22) Filed: Apr. 4, 2001

(30) Foreign Application Priority Data
Apr. 7, 2000 (JP) 2000-105904

(51) Int. Cl. G11C 29/00

(52) U.S. Cl. 365/200

(57) ABSTRACT

In a memory board 3 provided with: a printed wiring board 300 having a connector terminal 310; and memories 321 to 324 storing data used by an apparatus to which the printed wiling board 300 is attached, a memory controller 306 mediating data communication between the apparatus and the memories is provided. Based on stored setting information, the controller 360 converts the control content received from the main unit into the control content suitable for the access method specific to the memories 321 to 324, and performs read/write refresh.

This application is based on application No. 2000-105904 filed in Japan, the content of which is hereby incorporated by reference.

### BACKGROUND OF THE INVENTION

1. Field of the Invention

The present invention relates to a memory board attached to various kinds of apparatuses, for example, image forming apparatuses such as computers, printers and copiers, for memory addition, function extension or change of an added faction.

2. Description of the Related Art

In apparatuses to which a memory board such as an extended memory board is detachably attachable, the kinds of usable memory boards are limited by the configuration of the connection portion or whether it is a kind that can be controlled from the main unit or not. For example, even though a memory board has DRAMs as the memory devices, whether the memory board can be used or not depends on whether the DRAMs are EDO (extended data out) DRAMs or FP (first page) DRAMs. Moreover, there are many kinds of memories such as an SDRAM (synchronous-DRAM) and a rumbus DRAM.

In the field of copiers, digital copying machines have become common, and as the resolution of reading has increased, a memory of a larger capacity has been required. However, a large-capacity memory is not always necessary when copiers are used for some purposes. For this reason, only a memory of a basic capacity is provided on the board of the main unit, and the memory capacity is increased by adding an optional memory board as required. At present, SDRAMs are frequently used as the memory devices mounted on the memory board, Since the signal wiring is decided when the board of the main unit is manufactured, specific memory devices compatible with the signal wiring on the board of the main unit and the signals must be used in manufacturing the memory board. That is, memory devices of kinds incompatible with the wiring and the signal configuration cannot be used.

As a conventional method for increasing the manufacturability and the degree of freedom of memory boards, Japanese Laid-open Patent Application No. Hei 9-293938 discloses to provide a mode selection switch on a memory board. When the on-board memory devices have mode selection terminals, by selecting the mode with the switch, one memory board can be used for a plurality of purposes. It is unnecessary to manufacture a memory board for each purpose.

There is a memory board provided with an identification memory (for example, EEPROM) storing information on the on-board memory devices. The controller of the main unit that accesses the memory board reads the information from the identification memory, and accesses the memory board in a manner suitable for the kind of the memory devices.

In the structure provided with the mode selection switch as described above, although the range of uses of the memory board increases, it is necessary to set the switch on the memory board in accordance with the mode. Moreover, the memory board can only be used as memory boards of various types and modes, and it is necessary for the controller of the main unit to perform a memory control suitable for the type or the mode set on the memory board. That is; it is necessary for the controller of the main unit to have the capability of performing a plurality of kinds of memory controls.

In the structure provided with the identification memory, the memory devices can be selected only from among the existing kinds, so that there is a fear that memory devices of new specifications cannot be adopted. In addition, it is necessary for the controller of the main unit to change the content of the control in accordance with the result of the identification of the kind of the memory devices.

As described above, in the previously proposed structures, since it is necessary for the controller of the main unit to change the control method in accordance with the memory, the load on the main unit is heavy.

### SUMMARY OF THE INVENTION

An object of the present invention is to provide a memory board with which the degree of freedom of the change of the on-board memory devices is increased and the load on the main unit is lightened.

A memory board of the present invention comprises: a printed wiring board having a connector terminal; a memory device mounted on the printed wiring board, and storing data used by an apparatus to which the printed wiring board is attached; and a memory controller mediating data communication between the apparatus and the memory device, and the memory controller is a programmable device where the content of the mediation is changeable.

An image forming apparatus of the present invention comprises: a memory board; a connector for attaching the memory board; and a controller accessing the attached memory board to perform a control associated with image formation, wherein the memory board, which is connected to the connector, comprises: a printed wiring board having a connector terminal; a memory device mounted on the printed wiring board, and storing data used by an apparatus to which the printed wiring board is attached; and a memory controller mediating data communication between the apparatus and the memory device, and being a programmable device where the content of the mediation is changeable.

A memory board of the present invention comprises: a printed wiring board having a connector terminal; a memory device mounted on the printed wiring board, and storing data used by an apparatus to which the printed wiring board is attached; and a memory controller converting a control for the memory device transmitted from the apparatus into a control compatible with the kind of the memory device.

### BRIEF DESCRIPTION OF THE DRAWINGS

These and other objects and features of this invention will become clear from the following description, taken in conjunction with the preferred embodiments with reference to the accompanied drawings in which:

FIG. 1 is a view showing the general structure of a copier as an application example of a memory board according to an embodiment of the present invention;

FIG. 2 is a block diagram schematically showing a control system of the copier;

FIG. 3 is a view showing tie structure of the memory board,:

FIG. 4 is a view showing the signal configuration of the memory board; and

FIG. 5 is a view showing the structure of a memory board according to a second embodiment.

### DETAILED DESCRIPTION OF THE PREFERRED EMBODIMENTS

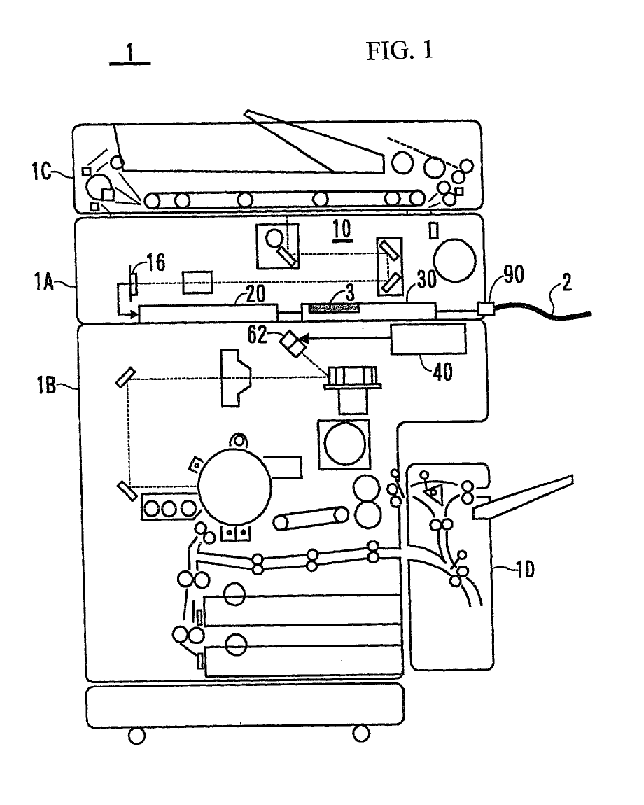

FIG. 1 is a view showing the general structure of a copier as an application example of a memory board according to an embodiment of the present invention. The copier 1 comprises: an image reader 1A that scans an image of an original; an electrophotographic printer 1B; an automatic document feeder (ADF) 1C; and a re-feed unit 1D for a purpose such as double-sided copying. By connecting a cable 2 to a connector 90, the user can use the copier 1 as a network printer.

In the image reader 1A, an image signal obtained by a scanning mechanism 10 and an image sensor (for example, CCD) 16 is converted into digital image data by an image processing circuit 20. The image data is transferred to a print data processor 40 of the printer 1B by way of a memory unit 30. Based on the image data, the print data processor 40 produces data for controlling the turning on and off of a semiconductor laser (CD) serving as an exposure light source. The electrophotographic process which is not directly related to the present invention will not be described.

The memory unit 30 has the capability of storing image data corresponding to a plurality of pages, and enables various kinds of memory copying such as rearrangement of pages, merging of pages, and re-copying with reading omitted. A memory board (extended memory) 3 which is an optional module for increasing the storage capacity is attached to the memory unit 30.

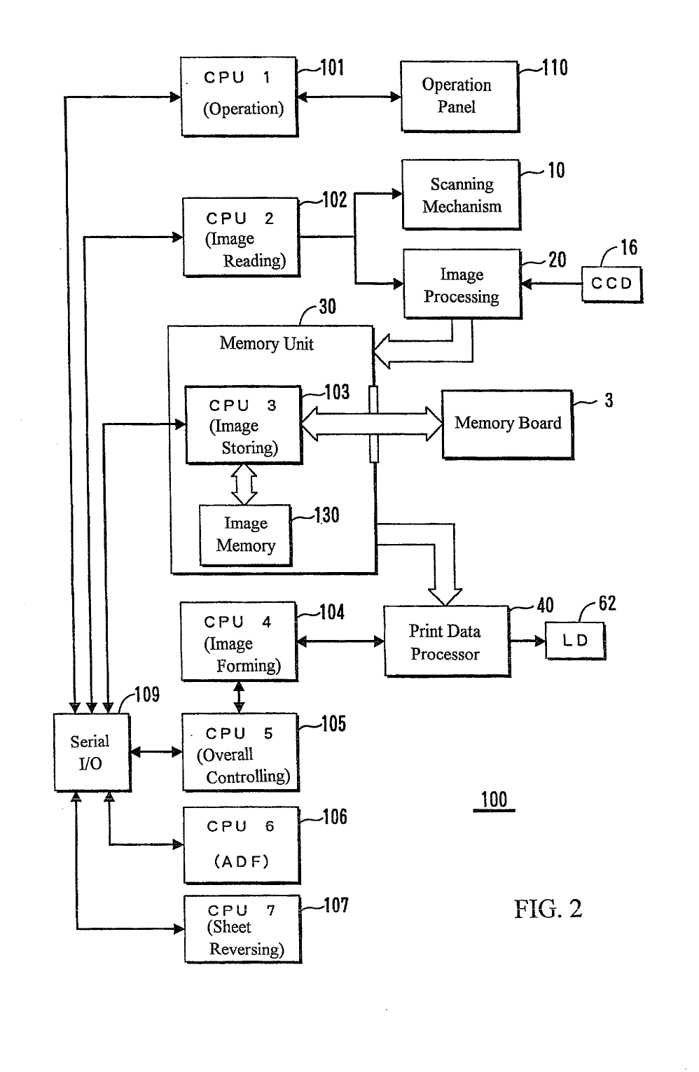

FIG. 2 is a block diagram schematically showing a control system of the copier.

The control system 100 mainly comprises seven CPUs 101 to 107 each provided with a ROM storing a program and a RAM serving as the work area for the execution of the program.

The CPU 101 performs controls associated with signal input from operation keys of an operation panel 110 and touch panel display. The CPU 102 controls the scanning mechanism 10 and the image processing circuit 20. The CPU 103 which is incorporated in the memory unit 30 controls access to an image memory 130 which is a fixed module and to the detachably attachable memory board 3. The CPU 103 is the main unit side controller for the memory board 3. Data transfer between a networked external apparatus and the copier 1 is performed through the memory unit 30. The CPU 104 controls a print head including the print data processor 40, and an image formation system. The CPU 105 performs processing for adjusting the overall timing of the control system 100 and setting the operation mode. The CPU 106 controls the automatic document feeder 1C. The CPU 107 controls the re-feed unit 1D. The CPUs assigned to the image reader 1A, the printer 1B, the automatic document feeder 1C and the re-feed unit 1D, respectively, communicate with one another through a serial input/output (I/O). Now, embodiments of the memory board 3 will be described.

First Embodiment

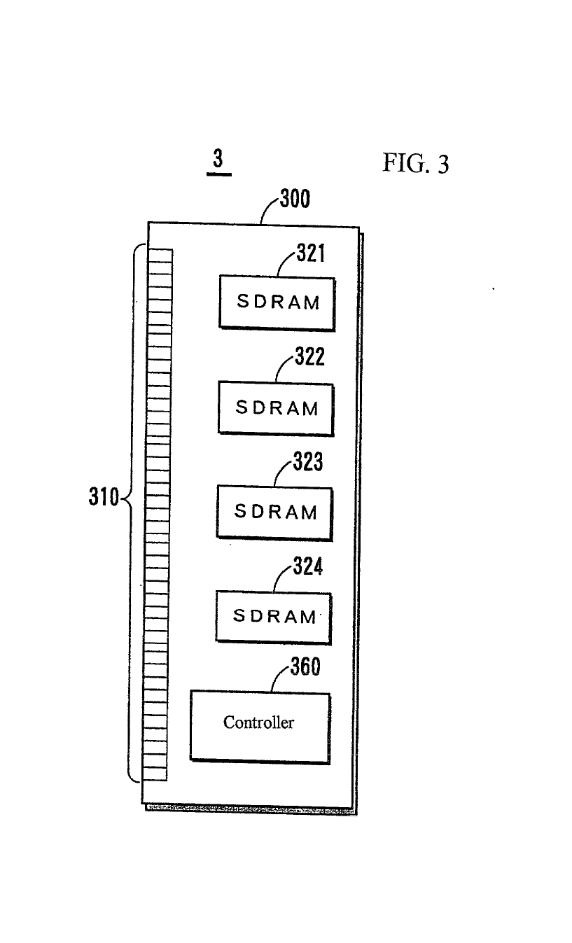

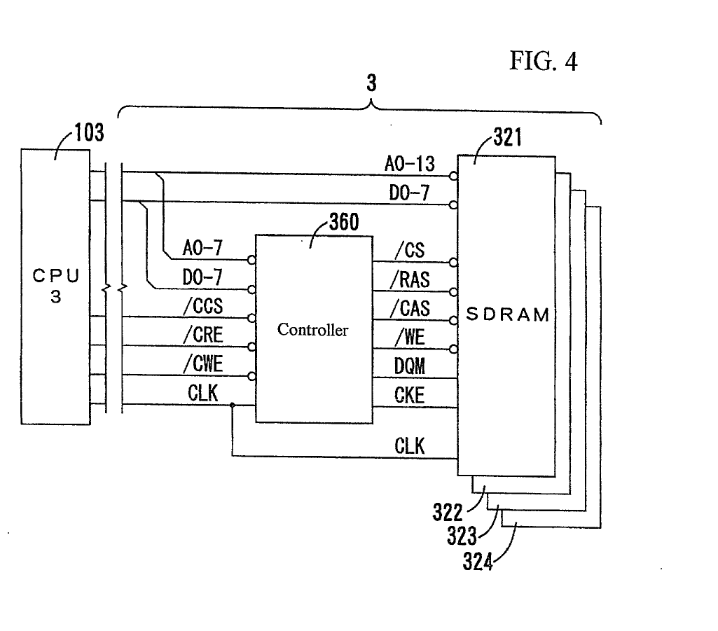

FIG. 3 is a view showing title structure of the memory board 3. FIG. 4 is a view showing the signal configuration of the memory board. The memory board 3 comprises: a printed wiring board 300 where a connector 3 10 for attachment and detachment is disposed on one end; SDRAMs 321, 322, 323 and 324 mounted as the memory devices; and a controller 360 having the function of mediating between the main unit side controller and the memory devices. The controller 360 stores setting information on the on-board memory devices, and converts the access control from the main unit side controller into the control suitable for the memory devices; based on the setting information

The SDRAMs 321 to 324 are controlled by the following signals:

A0-13: address bus (raw address, column address, bank address)

D0-7: data bus

/CS:chip select

/RAS: raw address and strobe command

/CAS: column address and strobe command

/WE: write enable

DQM: data mask

CKE: dock enable

CLK: clock

Here, the slashes indicate that the signals are negative.

To the memory board 3, the following control signals are input from the main unit side controller on the memory unit (that is, the CPU 103):

A0-13: address bus

D0-7: data bus

/CCS: controller chip select

/CRE: controller read enable

/CWE: controller write enable

CLK: clock

Of these control signals, A0-13, D0-7 and CLK are directly supplied to the SDRAMs 321 to 324. The other control signals (/CCS, /CRE and /CWE) are input not to the SDRAMs 321 to 324 but to the controller 360. A0-7 of A0-13, D0-7 and CLK are also input to the controller 360. The controller 360 shoulders output of the above-mentioned signals that control the SDRAMs 321 to 324 (/CS, /RAS, /CAS, /WE, DQM, CKE).

The CPU 103 which is the main unit side controller provides a read/write instruction to the controller 360 on the memory board by a predetermined specific single access method. Receiving the instruction, the controller 360 converts the received control content into the control content suitable for the access method specific to the SDRAMs based on the stored setting information, and performs read/write refresh. That is, the controller 360 mediates the access from the CPU 103 to the SDRAMs 321 to 324.

When a memory board having devices of a kind different from the SDRAMs 321 to 324 (for example, DRAMs) is attached to the memory unit 30, the CPU 103 attempts to access the DRAMs by the same method as when the memory board 3 having the SDRAMs is attached. The controller provided on the memory board having the DRAMs converts the control content to the one suitable for the access method specific to the DRAMs, and performs read/write refresh.

While in this embodiment, the access from the main unit to the extended memory is performed by the method using the signals A0-7, D0-7, /CCS, /CRE, /CWE and CLK, the access method is not limited thereto.

As described above, the controller on the memory board converts the instruction from the main unit side controller in accordance with the kind of the on-board memory devices. By doing this, various kinds of memory boards can be attached, and it is necessary for the main unit side controller to be provided with only one method to access the memory board, irrespective of the kind of the memory devices mounted on the memory board. When memory devices of a new type are mounted, it is unnecessary to change the control content of the main unit side controller. Consequently, the load on the main unit side controller is lightened.

Second Embodiment

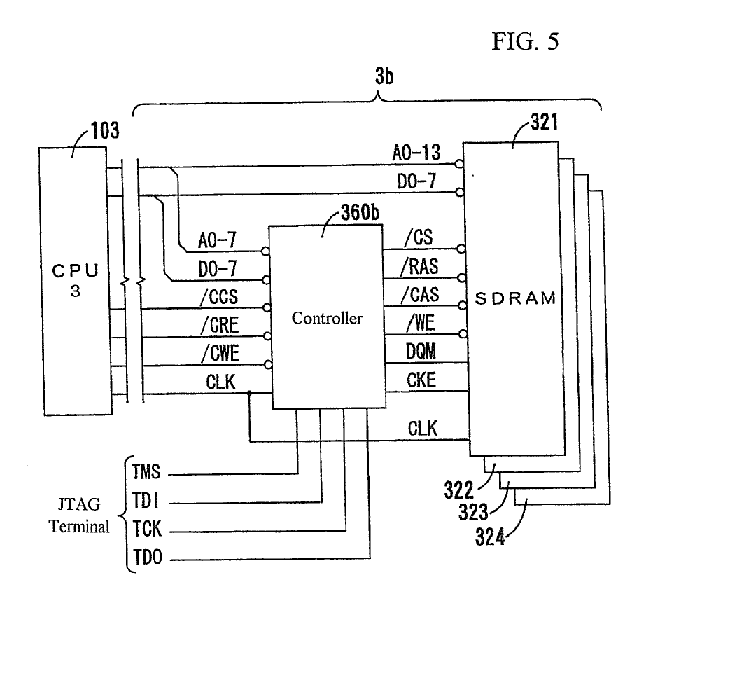

FIG. 5 is a view showing the structure of a memory board according to a second embodiment.

A memory board 3b of this embodiment also uses SDRAMs as memory devices. A characteristic of the memory board 3b is that a controller 360b can be programmed from the main unit side controller or other programmer devices. In the illustrated example, JTAG terminals are used for programming the controller 360b. At a stage of mounting on a printed wiring board, the controller 360b does not have the mediating function which the controller 360 of the first embodiment has, and the functions of the input and output terminals of the controller 360b are not established. By the controller 360b being programmed after the memory board 3b is mounted, the terminals are associated with control signals from the main unit and signals specific to the memory devices, so that the controller 360b obtains the mediating function. The CPU 103 of the main unit programs the controller 360b of the memory board 3b to have a predetermined function by use of the JTAG terminals, thereby enabling the use of the extended memory.

In the first embodiment, it is necessary to provide a specifically designed controller every time a memory board using a different kind of memory devices is manufactured. In this embodiment, however, by the controller 360b comprising a programmable controller device, commonality of the device is achieved. While the JTAG terminals are used for the programming in the illustrated example, the terminals used are not limited to the JTAG terminals, but specifically designed program terminals may be used.

As the programmable device, various kinds of programmable devices such as an FPGA (field programmable gate array) and a programmable ASIC may be used.

As described above; according to the structures of the embodiments, not only the degree of freedom of the change of the on-board memory devices is increased but also the load on the main unit side controller is lightened. In addition, by the controller on the memory board comprising a programmable device, commonality of the controller is achieved, so that cost is reduced.

Obviously, many modifications and variation of the present invention are possible in light of the above teachings. It is therefore to be understood that within the scope of the appended claims, the invention may be practiced other than as specifically described.

What is claimed is:

1. A memory board comprising:
a printed wiring board having a connector terminal;
a memory device mounted on the printed wiling board, and storing data used by an apparatus to which the printed wiring board is attached; and
a memory controller mediating data communication between the apparatus and the memory device,
wherein the memory controller is a programmable device where the content of the mediation is changeable.

2. The memory board as claimed in claim 1, wherein the memory controller converts a control sent from the apparatus into a control compatible with the kind of the memory device.

3. The memory board as claimed in claim 1, wherein the memory controller stores a setting information relevant to the memory device and mediates data communication according to the setting information.

4. An image forming apparatus comprising:
memory board;
a connector for attaching the memory board; and
a controller accessing the attached memory board to perform a control associated with image formation,
wherein the memory board, which is connected to the connector, comprises a printed wiring board having a connector terminal; a memory device mounted on the printed wiring board, and storing data used by an apparatus to which the printed wiring board is attached; and a memory controller mediating data communication between the apparatus and the memory device, and being a programmable device where the content of the mediation is changeable.

5. The image forming apparatus as claimed in claim 4, wherein the memory controller converts a control sent from the controller into a control compatible with the kind of the memory device.

6. The image forming apparatus as claimed in claim 4, wherein the memory controller is programmed by the controller of the image forming apparatus.

7. A memory board comprising:
a printed wiring board having a connector terminal;
a memory device mounted on the printed wiring board, and storing data used by an apparatus to which the printed wiring board is attached; and
a memory controller converting a control for the memory device transmitted from the apparatus into a control compatible with the kind of the memory device.

8. The memory board as claimed in claim 7, wherein the memory controller is a programmable device where the content of the conversion is changeable.

9. The memory board as claimed in claim 7, wherein the memory controller stores a setting information relevant to the memory device and converts control according to the setting information.
